(19) United States
(12) Patent Application Publication
(10) Pub. No.: US 2007/0135032 A1
(43) Pub. Date: Jun. 14, 2007

(54) Minimized exhaust air re-circulation around air cooled hardware cabinets

(75) Inventor: David Gang Wang, San Diego, CA (US)

Correspondence Address: JAMES M. STOVER;NCR CORPORATION, 1700 SOUTH PATTERSON BLVD, WHQ4, DAYTON, OH, 45479, US

(73) Assignee: NCR Corporation

(21) Appl. No.: 11/300,624

(22) Filed: Dec. 14, 2005

(51) Int. Cl. H05K 5/00

(52) U.S. Cl. 454/184

(57) ABSTRACT

Hardware cabinets contain air-cooled electronic components and are configured to operate in a data center or the like in which the cabinets are arranged in one or more rows and receive coolant air supplied to a cold-air aisle facing the cabinets. Heated air exiting the cabinets is directed to a hot-air aisle for HVAC system return in the data center. An air-flow device component of a hardware cabinet is positioned to create a curtain or wall of air extending from the housing to separate cold air in the cold-air aisle from hot air in the hot-air aisle. Hardware cabinets and retrofit kits using cross flow blowers are disclosed.

### BACKGROUND

In many data center environments, in which extensive electronic hardware is air-cooled, cooling system inefficiencies result when heated exhaust air from equipment prematurely mixes with chilled coolant air before it is used for cooling. In a typical data center, large numbers of air-cooled electrical hardware cabinets are arranged multiple rows. The cabinets generally contain numerous electrical components and devices, often in racks of electrical hardware chassis enclosures, for which air-cooling is required. With the typically extensive deployments of electrical heat producing hardware, a substantial amount of heat is generated. Each row of hardware cabinets typically faces a cold-air aisle which is supplied with chilled coolant air by the data center's HVAC system. The chilled air may be supplied from below in a raised floor environment or from above when overhead cold air delivery systems are used. The chilled air is generally drawn into the hardware cabinets, through inlet vents in cabinet walls or doors, and heated as the components inside the cabinet are cooled. The heated air is typically exhausted into a hot-air aisle behind the cabinets for return to the HVAC system, to remove absorbed heat and regenerate chilled air.

Effective cooling of hardware cabinets in data centers generally depends not only on chilled air temperatures and volumetric flow generated the HVAC system, but also on efficiency of local cold air delivery to each cabinet over the data center floor space. Optimal delivery of cold air to locations throughout a data center can be more difficult than producing a theoretically adequate volume of chilled air at sufficiently low temperatures. Undersupply of available cold air or non-uniform flow distribution to individual hardware cabinets has been common in many data centers. Mixing of chilled air before its use with heated exhaust air results in significant cooling inefficiencies in many systems.

As a result of inadequate cold air delivery systems, high temperatures have been observed in many data centers, due to warm air in the vicinity of cabinet cold air inlet areas. Warm exhaust air even from higher elevations sometimes produces coolant air deficits by mixing with coolant air before the coolant air enters the cabinets. When warmed exhaust air passes the top of a cabinet, it is susceptible to being drawn into cabinet inlets, especially when the system cold air supply is insufficient to meet the volumetric cooling airflow requirements of the cabinet. Further, laws of physics dictate airflow will follow paths with least flow impedance or resistance. Exhaust air may go directly from the back sides of cabinets in hot-air aisles of data centers to the return of a computer room air conditioning (CRAC) unit close by, but it may also go from a hot-air aisle to a CRAC return by passing through a cold-air aisle. Consequently, heated exhaust air may re-circulate back to the hardware cabinets, resulting in higher inlet air temperatures and reduced electronics reliability. When future hardware equipment solutions with growing power densities are employed, the hot air recirculation and higher temperatures can potentially be even more severe and possibly hamper the deployment of the future equipment.

Current front to back forced air cooled equipment and data centers using such equipment can thus inadequately control how exhaust air is dispersed to the environment. Exhaust air re-circulating to coolant inlets of hardware equipment, or mixing with cold coolant air before it reaches the equipment, results in cooling system inefficiencies. Proposed solutions to this, such as cabinets with water cooling or individually adjustable coolant air availability, appear to be complex or expensive to implement.

### SUMMARY

Hardware cabinets contain air-cooled electronic components and are configured to operate in a data center or the like in which the cabinets are arranged in one or more rows and receive coolant air supplied to a cold-air aisle facing the cabinets. Heated air exiting the cabinets is directed to a hot-air aisle for HVAC system return in the data center. An air-flow device component of a hardware cabinet is positioned to create a curtain or wall of air extending from the housing to separate cold air in the cold-air aisle from hot air in the hot-air aisle. Hardware cabinets and retrofit kits using cross flow blowers are disclosed.

Other features and advantages will become apparent from the description and claims that follow.

### BRIEF DESCRIPTION OF THE DRAWINGS

FIG. 1 is a sectional schematic of a raised floor computer data center.

FIG. 2 shows a traditional air-cooled hardware cabinet with ideal cold and hot airflow shown around and through the cabinet.

FIG. 3 shows recirculation airflow of heated exhaust air around and to the cold aisle side of the air-cooled hardware cabinet shown in FIG. 2.

FIG. 4 shows a hardware cabinet having a blower that creates an air curtain separating cooled intake supply air outside the cabinet from hot air exiting the cabinet.

### DEATAILED DESCRIPTION

A typical data center includes multiple electronics hardware cabinets arranged in rows, each separated by aisles wide enough to allow human access. Electronics within the cabinets are generally cooled by chilled air entering from the front side of the cabinet. This air is heated by heat-generating components within the cabinets and is generally exhausted from the backside of each cabinet. As a result, aisles that separate the cabinets tend to be designated as “cold-air aisles” into which coolant air is supplied, and “hot-air aisles” into which heated air is exhausted for return and re-cooling by the data center's A/C system.

The data center may be a computer room, telecommunications center or like facility in which electronic air-cooled hardware cabinets are arranged in a row between a “cold-air aisle” and “hot-air aisle” and maintained at controlled temperatures.

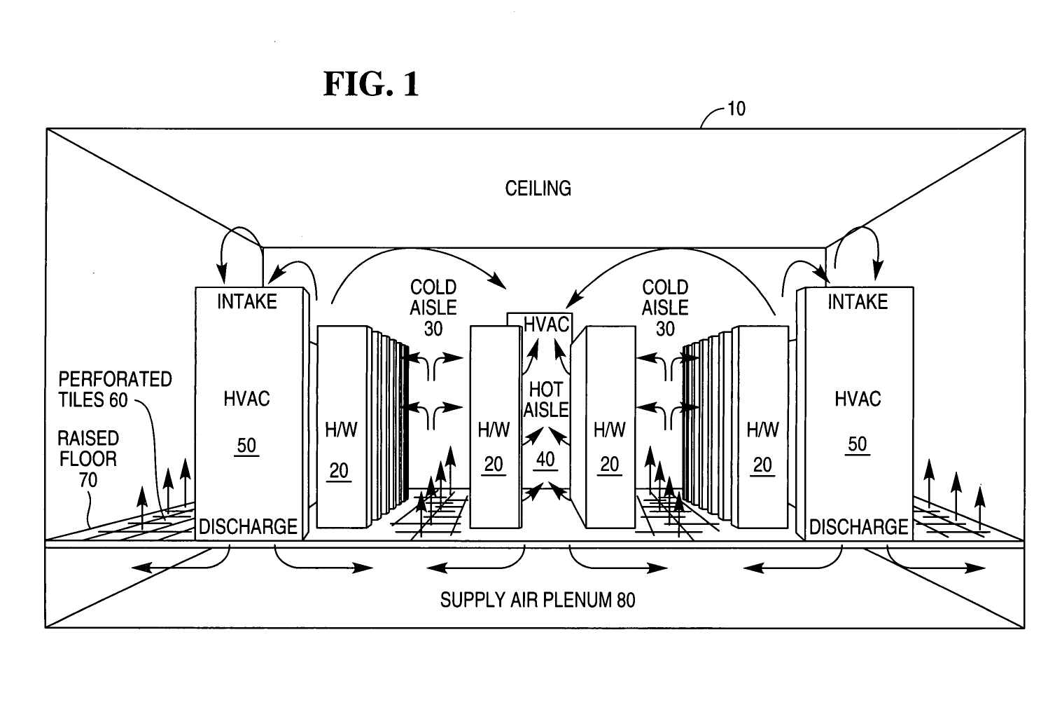

FIG. 1 shows a typical data center 10 with hardware cabinets 20 arranged in multiple rows between cold-air aisles 30 and hot-air aisles 40. Cold air is supplied into the cold-air aisles 30 by HVAC units 50 through perorated tiles 60 in a raised floor 70. Coolant air is supplied to the hardware cabinets 20 from the cold-air aisles 30 which the front sides of the hardware cabinets 20 face. The coolant air enters, for example, through vents in the front sides or doors of the hardware cabinets 20. The coolant air removes heat from electronic components inside the cabinets and exits the cabinets as hot air exhaust into the hot-air aisles 40. Exhaust air in hot-air aisles 40 is returned through elevated intakes of the HVAC units 50 and re-circulated as cold air to a supply air plenum 80 below the raised floor 70. Alternatively cold air is supplied to the cold-air aisles 30 by an overhead cold air delivery system (not shown).

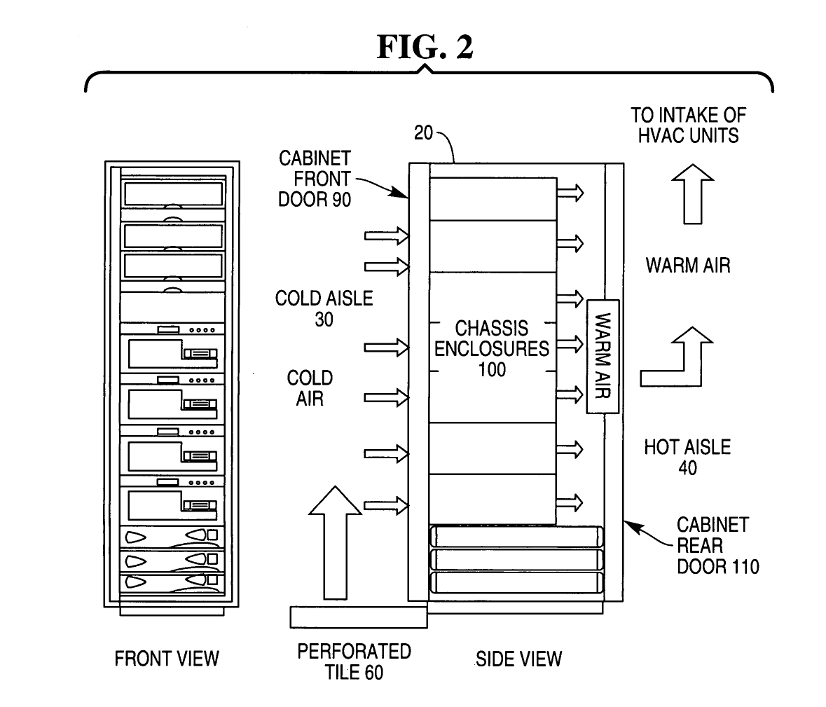

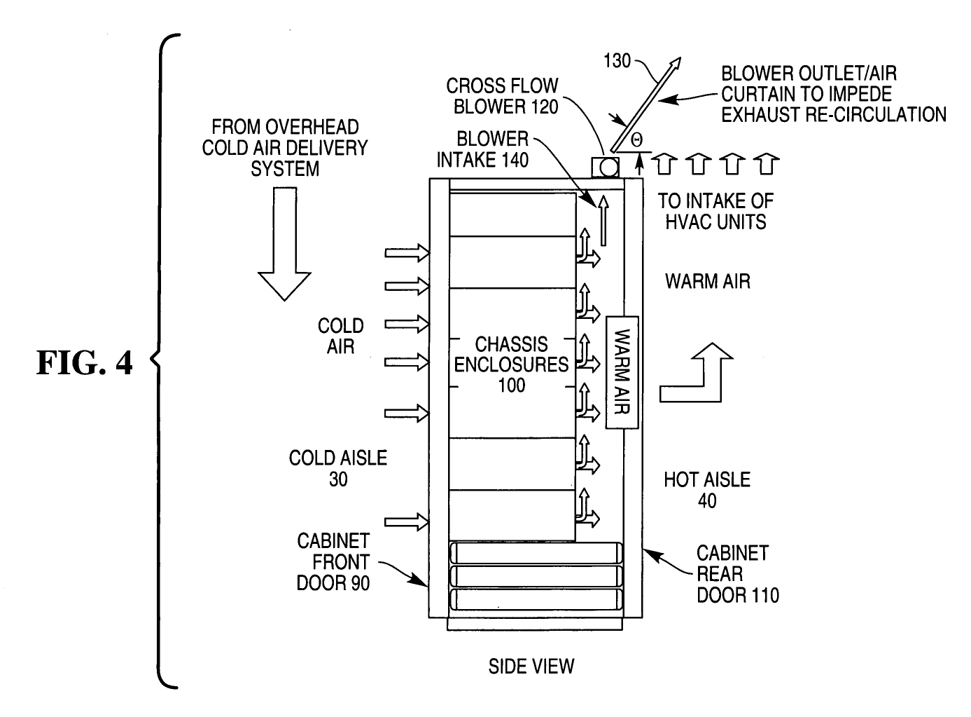

FIG. 2 shows an ideal air flow through a traditional hardware cabinet 20. As shown, cold air enters through inlets in a front door 90 of the hardware cabinet 20 from the associated cold- air aisle 30. In the illustration, the cold air is supplied from below through perforated floor tile 60, such as is illustrated in FIG. 1. Alternatively, cold air could be supplied to the cold-air aisle 30 from above by an overhead cold air delivery system as shown in FIG. 4. Heated air, after cooling electrical components and devices in chassis enclosures 100 in the hardware cabinet 20, exits outlets in the cabinet rear door 110 in the back side of the hardware cabinet 20. The exiting hot exhaust air from the hardware cabinet 20 is directed into the hot-air aisle 40 faced by the back side of the hardware cabinet 20. Air exhausted from the cabinets 20 rises for return to intakes of HVAC units.

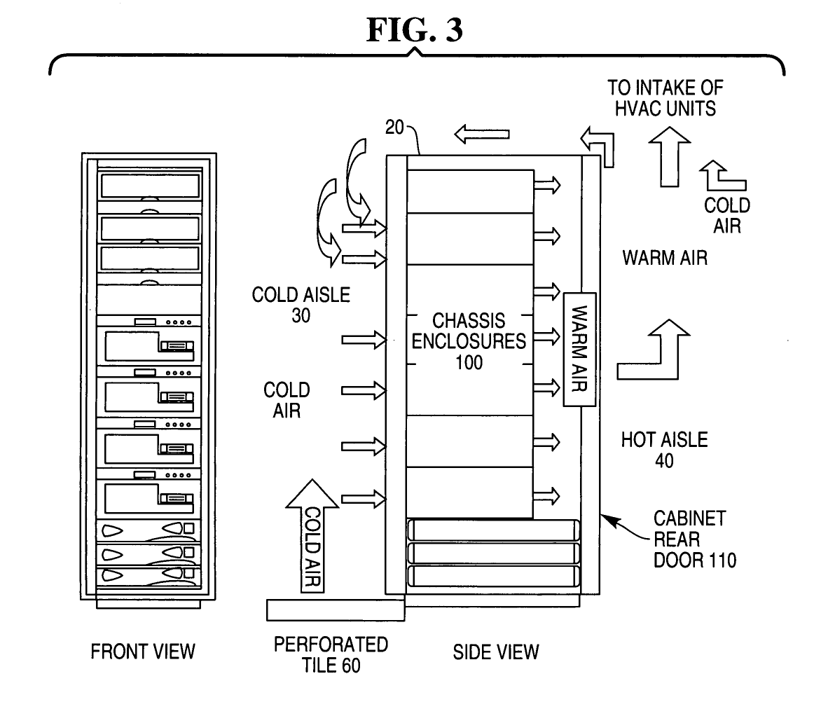

FIG. 3 shows a suboptimal air flow around a hardware cabinet 20 similar to that shown in FIG. 2. As shown, a portion of hot air exhausted from the hardware cabinet 20 circulates over the top of the hardware cabinet 20 and mixes with cold coolant supply air on the cold-air aisle side of the hardware cabinet 20. Similarly a portion of cold air supplied to the cold-air aisle sometimes circulates to the hot-air aisle side of the hardware cabinet 20 and mixes with hot air exhausted from the cabinet 20. This mixing of cold and hot air results in cooling inefficiencies in the data center cooling system. As a result, cooling of hardware cabinets 20 can be inadequate even though in theory a system generates sufficient cooled air to meet the cooling needs of the hardware cabinets 20.

FIG. 4 shows a system incorporating an air-flow device 1 20 mounted on top of the hardware cabinet 20 providing an air curtain or “wall” of air 130 extending upwardly from the hardware cabinet 20. Extends upwardly from the back side of the hardware cabinet 20, the air curtain 130 impedes mixing of hot exhaust air with cold coolant intake supply air outside the cabinet 20. The air curtain 130 separates cold air on the cold-air aisle side of the hardware cabinet 20 from the hot air on the hot-air aisle side of the cabinet 20. This improves efficiencies of the data center cooling system and the rates at which components in the cabinet 20 are cooled. As shown, the air curtain 130 extends from the hardware cabinet 20 at an angle Θ, extending into the hot-air aisle 40. The air curtain 130 is formed from hot air drawn from inside the cabinet 20 through the intake 140 of the air-flow device 120. The air-flow device 120 exhausts and forms the air curtain 130 from hot air drawn from the hardware cabinet 20. Alternatively the intake of air by the air-flow device 120 could be from outside the cabinet 20, e.g., for an air curtain 130 at a different temperature.

The hardware cabinet 20 shown in FIG. 4 incorporates an air-flow device 120 in the form of one or more cross flow blowers mounted on top of the hardware cabinet 20. The illustrated cross flow blowers collectively extend substantially across the width of the cabinet 20 and thus generate an air curtain or wall of air 130 which extends substantially across the width of the cabinet 20. The generated air curtain 130 is in the form of a sheet or layer of moving air extending from the cabinet 20 and serving as a barrier to separate and impede mixing of cold air on the front side of the cabinet 20 and hot air on the back side of the cabinet 20 in this example.

The hardware cabinet 20 shown in FIG. 4 contains air cooled electronics hardware such as electronics components and devices in hardware chassis enclosures 100 in a rack inside the hardware cabinet 20. The illustrated hardware cabinet 20 also includes an exterior housing which is structured or configured to receive coolant air from the cold-air aisle side of the cabinet 20 as shown. Intake of the coolant air is through inlets such as vents in a front door structure 90 at the front of the cabinet 20. Similarly, the exterior housing of the illustrated cabinet 20 includes a back door structure 110 at the back of the cabinet 20. The back door structure 110 has outlets such as vents through which heated air exits at the hot-air aisle side at the back of the cabinet 20. However which side of the cabinet 20 faces the cold-air aisle and which side faces the hot-air aisle side and the exact nature of the air inlets and outlets in the housing of the cabinet 20 would obviously generally not be critical to the functioning of the air curtain 130. Variations among these elements can be used as needs or requirements may dictate, such as accommodating the configuration and structure of already existing equipment to which an air-flow device 120 may be retrofitted, as will be described.

An air-flow device 120, e.g., one or more cross flow blowers, can be provided with new equipment, as a component of a new hardware cabinet 20, or it can be provided as part of a retrofit kit to retrofit existing hardware cabinets 20 already installed or to be installed in a data center. A retrofit kit would typically include the air-flow device 120, mounting hardware to mount the air-flow device 120 on the cabinet 20 to enable an air curtain 130 to be established and extended outwardly form the cabinet 20, and access to instructions directing users how to operate and install the air-flow device 120. The instructions would generally be physically included in the retrofit kit or otherwise made available to the user. As already indicated the air-flow device 120 can be configured to draw heated air from inside the hardware cabinet 20, e.g., through a blower intake 140 shown in FIG. 4. This would obviously add to the air-flow though the cabinet 20 and improve rates of cooling. However the air-flow device 120 can alternatively be configured to draw air from outside the cabinet 20, which would facilitate retrofitting to equipment not already having openings or vents through which a retrofitted air-flow device 120 could draw air. Otherwise such openings or vents would have to be added as part of the retrofitting process.

To enable adjustments in the functioning of the air-curtain 130, the air-flow device 120 would have a control mechanism to allow adjustments in the air-flow rate of air output from the air-flow device 120. To permit adjustment of the angle Θ, e.g., or upward direction of the air curtain 130, an adjustment mechanism in the air-flow device 120 or its mounting hardware would be provided. The angle Θ could be increased to an angle of ninety degrees or more if appropriate for cooling efficiency improvements. Such adjustments would permit empirical fine tuning of the air curtain 130, e.g., to accommodate different ceiling heights, or otherwise optimize data center cooling system efficiencies.

The text above describes one or more specific embodiments or examples of a broader invention. The invention is also carried out in a wide variety of other alternative ways and is thus not limited to those described here. Many other embodiments of the invention are also within the scope of the following claims.

What is claimed is:

1. For use in a data center or the like in which multiple hardware cabinets are arranged in a row and receive coolant air supplied to a cold-air aisle facing the cabinets, and in which heated air exiting the cabinets is directed to a hot-air aisle behind the cabinets, a hardware cabinet comprising:
air-cooled electronic components to be cooled by the coolant air;
a housing having an inlet to receive coolant air from the cold-aisle to cool the electronic components, and an outlet to exhaust hot air to the hot-air aisle; and
an air-flow device mounted to create a curtain of air extending from the housing to impede mixing of cold air in the cold-air aisle with hot air in the hot-air aisle.

2. For use in a data center in which multiple hardware cabinets housing electronic components are arranged in multiple rows separated by at least one cold-air aisle through which cold air is supplied to the hardware cabinets, and in which hot air is exhausted by the cabinets into hot-air aisles, a hardware cabinet comprising:
electronics hardware;
a housing for the hardware, where the housing is structured to allow cold air to enter from the cold-air aisle and hot air to exit to the hot-air aisle; and
an air-flow device positioned to create a curtain or wall of air extending from the housing to separate cold air in the cold-air aisle from hot air in the hot-air aisle.

3. An air cooled hardware cabinet having one or more exhaust air outlets located to exhaust coolant air though the back side of the cabinet, and one or more cross flow blowers mounted on top of the cabinet to provide an outwardly directed air curtain, confining hot air exhausted from the cabinet to space facing the cabinet's back side.

4. An air cooled hardware cabinet having one or more coolant air inlets located to receive coolant air though the front of the cabinet, and one or more blowers mounted on top of the cabinet and substantially across the width of the cabinet to provide an upwardly directed curtain of air extending substantially across the width of the cabinet, impeding flow of exhausted hot air from the back of the cabinet to the front of the cabinet.

5. A retrofit kit enabling retrofitting an air cooled hardware cabinet for improved cooling efficiency in a data center, comprising an air-flow device by which to establish an air curtain of exhausted hot air from the cabinet, hardware for mounting the air-flow device on the cabinet so that the air curtain will extend outwardly from the cabinet, impeding flow of exhausted hot air from the back of the cabinet to the front of the cabinet, and access to instructions directing users how to install and operate the air-flow device.

6. The retrofit kit of claim 5 in which the air-flow device comprises one or more cross flow blowers collectively sized to extend substantially across the width of the cabinet, enabling the air curtain to extend substantially across the width of the cabinet.

7. The retrofit kit of claim 5 in which the air-flow device includes a control mechanism by which the air-flow rate of air output from the device can be adjusted.

8. The retrofit kit of claim 5 in which the direction of air exhaust from the air-flow device is adjustable to permit adjustment of the upward direction of the air curtain.

9. A retrofit kit enabling retrofitting an air cooled hardware cabinet for improved cooling efficiency in a data center, comprising an air-flow device by which to establish an air curtain of air drawn from outside the cabinet, hardware for mounting the air-flow device on the cabinet so that the air curtain will extend outwardly from the cabinet, impeding flow of exhausted hot air from the back of the cabinet to the front of the cabinet, and instructions directing users how to install and operate the air-flow device.

10. A hardware cabinet containing air cooled electronics components and having one or more inlets that receive coolant air flowing into the cabinet, one or more outlets that exhaust hot air from the cabinet, and one or more blowers mounted on top of the cabinet and extending substantially across the cabinet's width, to provide an upwardly directed curtain of air extending substantially across the cabinet's width, impeding circulation of exhausted warmed air across the curtain of air.

11. A hardware cabinet containing air cooled electronics components and having one or more inlets located to receive coolant air from the front side of the cabinet, one or more outlets that exhaust hot air from the back side of the cabinet, and a cross flow blower mounted on top of the cabinet to provide an upwardly directed air curtain, confining hot air exhausted from the cabinet to space facing the cabinet's back side.

12. The hardware cabinet of claim 11 in which the curtain of air is formed from heated air drawn from inside the cabinet by the blower.

13. The hardware cabinet of claim 11 in which the blower is positioned to draw heated air from inside the cabinet and exhaust that heated air out of the cabinet.

14. The hardware cabinet of claim of claim 11 in which the curtain of air is directed upwardly and backwardly into the space facing the cabinet's back side.

15. The hardware cabinet of claim of claim 11 in which the curtain of air is directed upwardly and forwardly into the space facing the cabinet's front side.

16. The hardware cabinet of claim 11 in which the upward direction of the air curtain is adjustable to optimize air cooling efficiencies in a data center or the like.

17. The hardware cabinet of claim 11 in which the airflow rate of the blower is adjustable to optimize air cooling efficiencies in a data center or the like.

18. The hardware cabinet of claim 17 in which the upward direction of flow of the air curtain is adjustable to optimize air cooling efficiencies in the data center.

19. An air cooled electronic chassis cabinet having one or more inlets that receive coolant air flowing into the cabinet, and one or more cross flow blowers mounted on top of the cabinet to facilitate cooling of electronic components and devices in the cabinet.

20. A cool air curtain produced by a cross flow blower and extending from an air-cooled hardware cabinet in a data center or the like, where the air curtain separates cold air in a cold-air aisle from hot air in a hot-air aisle in the data center.
